(19) United States
(12) Patent Application Publication
(10) Pub. No.: US 2014/0183177 A1
(43) Pub. Date: Jul. 3, 2014

(54) SEMICONDUCTOR DEVICE AND METHOD FOR DRIVING THE SAME

(71) Applicant: Kabushiki Kaisha Toshiba, Minato-ku (JP)

(72) Inventors: Chiharu OTA, Kanagawa-ken (JP); Kazuto TAKAO, Ibaraki-ken (JP); Johji NISHIO, Tokyo (JP); Takashi SHINOHE, Kanagawa-ken (JP)

(73) Assignee: Kabushiki Kaisha Toshiba, Minato-ku (JP)

(21) Appl. No.: 14/109,103

(22) Filed: Dec. 17, 2013

(30) Foreign Application Priority Data
Dec. 28, 2012 (JP) 2012-287770

(51) Int. Cl. H01L 23/34; H01L 29/16

(52) U.S. Cl. CPC H01L 23/345; H01L 29/1608
USPC 219/209; 257/77; 219/494

(57) ABSTRACT

According to one embodiment, a semiconductor device includes a first semiconductor region, a second semiconductor region, a first electrode and a heat generation portion. The first semiconductor region includes n-type silicon carbide. The second semiconductor region is provided on a portion of the first semiconductor region. The second semiconductor region includes p-type silicon carbide. The first electrode provided on the first semiconductor region and the second semiconductor region. The heat generation portion is provided on the second semiconductor region.

### CROSS-REFERENCE TO RELATED APPLICATIONS

This application is based upon and claims the benefit of priority from Japanese Patent Application No. 2012-287770, filed on Dec. 28, 2012; the entire contents of which are incorporated herein by reference.

### FIELD

Embodiments described herein relate generally to a semiconductor device and a method for driving the same.

### BACKGROUND

Silicon carbide (SiC) has excellent physical properties exhibiting 3 times the band gap, approximately 10 times the breakdown field strength, and approximately 3 times the thermal conductivity compared to silicon (Si). Utilizing these properties of SiC allows a semiconductor device having excellent low-loss and high temperature operation to be realized. Examples of unipolar devices include a Schottky barrier diode (SBD) and a junction barrier Schottky (JBS) diode. By using SiC in these unipolar devices, it is possible to realize higher breakdown voltage and lower on voltage. In semiconductor devices using SiC, it is important to obtain a stable on voltage.

### BRIEF DESCRIPTION OF THE DRAWINGS

FIG. 1 is a schematic cross-sectional view illustrating an example of a semiconductor device according to the first embodiment;

FIG. 2 illustrates a controller;

FIG. 3 is a flowchart illustrating a driving method of the semiconductor device according to this embodiment;

FIG. 4 is a graph showing the current-voltage characteristic;

FIG. 5A to FIG. 6C are schematic cross-sectional views illustrating a manufacturing method for the semiconductor device;

FIG. 7 is schematic cross-sectional view illustrating an example of a semiconductor device according to the third embodiment;

FIG. 8 is schematic cross-sectional view illustrating an example of a semiconductor device according to the fourth embodiment; and

FIG. 9 is a schematic cross-sectional view illustrating the configuration of a semiconductor device according to the fifth embodiment.

### DETAILED DESCRIPTION

In general, according to one embodiment, a semiconductor device includes a first semiconductor region, a second semiconductor region, a first electrode and a heat generation portion. The first semiconductor region includes n-type silicon carbide. The second semiconductor region is provided on a portion of the first semiconductor region. The second semiconductor region includes p-type silicon carbide. The first electrode provided on the first semiconductor region and the second semiconductor region. The heat generation portion is provided on the second semiconductor region.

Various embodiments will be described hereinafter with reference to the accompanying drawings. In the following description, the same reference numeral is applied to the same member, and for members that have been described once, the description is omitted as appropriate.

Also, in the following description, the n⁺, n, n⁻ and p⁺, p, and p⁻ symbols show relative high and low impurity concentrations in the conductivity types. In other words, n⁺ has a relatively higher n-type impurity concentration than n, and n⁻ has a relatively lower n-type impurity concentration than n. Also, p⁺ has a relatively higher p-type impurity concentration than p, and p⁻ has a relatively lower p-type impurity concentration than p.

### First Embodiment

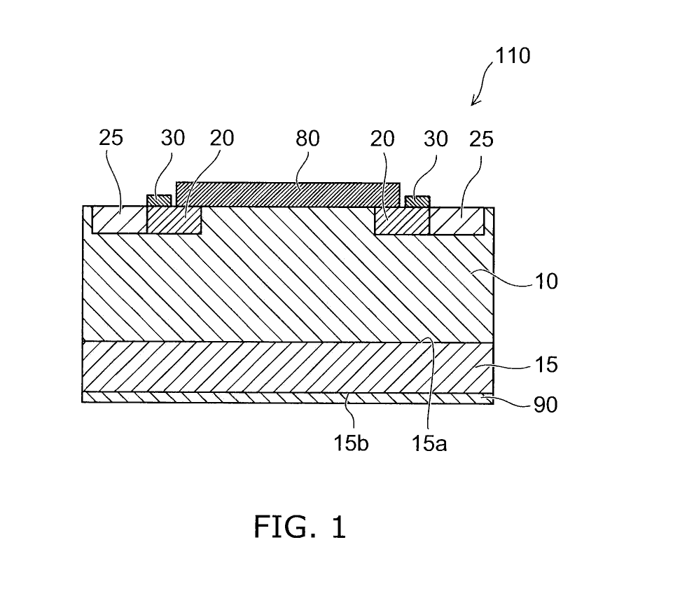

FIG. 1 is a schematic cross-sectional view illustrating an example of a semiconductor device according to the first embodiment.

As illustrated in FIG. 1, a semiconductor device 110 according to the first embodiment includes a first semiconductor region 10, a second semiconductor region 20, a first electrode 80, and a heat generation portion 30. Also, the semiconductor device 110 includes a substrate 15, a second electrode 90, and a third semiconductor region 25. The semiconductor device 110 is, for example, a Schottky barrier diode (hereafter referred to as “SBD”).

The substrate 15 is an n-type (n⁺ type) semiconductor region. The substrate 15 includes, for example, n⁺ type SiC. In this embodiment, the substrate 15 includes hexagonal SiC (for example, 4H—SiC). The substrate 15 is a bulk substrate of SiC fabricated by, for example, a sublimation method.

The substrate 15 includes a first surface 15a. The first surface 15a of the substrate 15 is a surface of a wafer that includes SiC. The first surface 15a is a boundary face between the substrate 15 and the first semiconductor region 10. In this embodiment, the first surface 15a of the substrate 15 is inclined at not less than 0 degrees and not more than 8 degrees with respect to the hexagonal SiC face, which is the (0001) face. For example, the substrate 15 is an off substrate such as a 2-degree off substrate, a 4-degree off substrate, an 8-degree off substrate, or the like. Here, the surface of the SiC substrate 15 may be an Si face, or it may be a C face. Within the substrate 15, which is an off substrate, there are basal plane dislocations within the basal plane.

The substrate 15 is doped with n-type impurities (for example, nitrogen (N)), and the impurity concentration is, for example, not less than 1×10¹⁸ cm⁻³ and not more than 1×10²⁰ cm⁻³. In this embodiment, the impurity concentration is approximately 5×10¹⁸ cm⁻³.

The first semiconductor region 10 includes n-type (n⁻ type) SiC. The first semiconductor region 10 is formed by, for example, epitaxial growth on the first surface 15a of the substrate 15. The first semiconductor region 10 has the same crystal structure as the substrate 15.

The thickness of the first semiconductor region 10 is determined from the design of the voltage breakdown characteristics and other characteristics. The thickness of the first semiconductor region 10 is, for example, not more than approximately 200 micrometers (μm).

The first semiconductor region 10 includes n-type impurities (for example, N). The impurity concentration of the first semiconductor region 10 is less than the impurity concentration of the substrate 15. The impurity concentration of the first semiconductor region 10 is, for example, not less than 5×10¹⁴ cm⁻³ and not more than 1×10¹⁷ cm⁻³.

The second semiconductor region 20 is provided on a portion of the first semiconductor region 10. The thickness of the second semiconductor region 20 is, for example, approximately not less than 0.1 μm and not more than 2 μm. The second semiconductor region 20 is disposed so as to, for example, surround the peripheral edge of the first electrode 80.

The second semiconductor region 20 includes p-type (p⁺ type) SiC. The second semiconductor region 20 includes p-type impurities (for example, aluminum (Al) or boron (B)). The impurity concentration of the second semiconductor region 20 is, for example, not less than 1×10¹⁸ cm⁻³ and not more than 1×10²¹ cm⁻³. The second semiconductor region 20 forms a p-n junction with the first semiconductor region 10. The second semiconductor region 20 is in ohmic contact with the first electrode 80.

The first electrode 80 is provided on the first semiconductor region 10 and the second semiconductor region 20. The first electrode 80 is provided on a portion of the second semiconductor region 20. In other words, the second semiconductor region 20 includes a portion in contact with the first electrode 80, and a portion that is not in contact with the first electrode 80.

The first electrode 80 is in ohmic contact with the second semiconductor region 20. The first electrode 80 forms a Schottky barrier junction with the first semiconductor region 10. The first electrode 80 is, for example, an anode electrode of an SBD. Nickel (Ni) may be used, for example, in the first electrode 80. The first electrode 80 is not limited to a single material. For example, a portion of the first electrode 80 in contact with the second semiconductor region 20 may form ohmic contact using Ni, and a portion of the first electrode 80 in contact with the first semiconductor region 10 may form a Schottky barrier junction using Ti or the like.

The second electrode 90 is formed so as to contact a second surface 15b of the substrate 15. Ni, for example, is used in the second electrode 90. The second electrode 90 is, for example, a cathode electrode of an SBD.

The third semiconductor region 25 is provided on a portion of the first semiconductor region 10. The third semiconductor region 25 is disposed so as to surround the outer side of the second semiconductor region 20. The thickness of the third semiconductor region 25 is, for example, approximately not less than 0.1 μm and not more than 2 μm.

The third semiconductor region 25 includes p-type (p⁻ type) SiC. The third semiconductor region 25 includes p-type impurities (for example, Al or B). The impurity concentration of the third semiconductor region 25 is lower than the impurity concentration of the second semiconductor region 20. The impurity concentration of the third semiconductor region 25 is, for example, not less than 5×10¹⁶ cm⁻³ and not more than 5×10¹⁸ cm⁻³. The third semiconductor region 25 is, for example, a termination region of the SBD.

The heat generation portion 30 is formed on a portion of the second semiconductor region 20 where the first electrode 80 is not provided. The heat generation portion 30 is formed, for example, along the second semiconductor region 20.

For example, a metal silicide such as MoSi₂ or WSi or a metal oxide is used in the heat generation portion 30. A resistance heating element (a material having a resistance value higher than the resistance value of the second semiconductor region 20) may be used as the heat generation portion 30. As a result of the heat generated by the heat generation portion 30, a portion of the first semiconductor region 10 is heated to not less than 350° C.

Next, the operation of the semiconductor device 110 is described. When a voltage is applied so that the first electrode 80 becomes positive (forward direction) relative to the second electrode 90 of the semiconductor device 110, electrons from the first electrode 80 that overcome the Schottky barrier flow to the second electrode 90 via the first semiconductor region 10 and the substrate 15.

On the other hand, when a voltage is applied so that the first electrode 80 becomes negative (reverse direction) relative to the second electrode 90 of the semiconductor device 110, electrons cannot easily overcome the Schottky barrier between the first electrode 80 and the first semiconductor region 10, so the flow of current is suppressed.

Here, in the semiconductor device 110, when an operation of switching between the application of a positive voltage and the application of a negative voltage is repeated, current that exceeds a predetermined current value (for example, surge current) may be generated. If a surge current is generated, holes are injected from the first electrode 80 to the second semiconductor region 20 and the first semiconductor region 10, and conductivity modulation occurs. In this way, a tolerance to the surge current is obtained.

When holes are injected into the first semiconductor region 10 due to surge currents or the like, there is a possibility that stacking faults will be generated originating at the basal plane dislocations. A fluctuation (variation) in the ON voltage of the semiconductor device 110 is generated by the occurrence of these stacking faults. In other words, it is considered that the stacking faults cause a high resistance region. Therefore, the ON voltage is raised by the occurrence of the stacking fault. The inventors of the present application discovered the new issue that even in the case of a unipolar device such as an SBD, when there is a region with conductivity modulation in a portion thereof, stacking faults occurring in that region can cause an increase in the ON voltage.

In the semiconductor device 110, as a result of the heating of the first semiconductor region 10 by the heat generation portion 30, stacking faults occurring in the first semiconductor region 10 are reduced. In this way, it is possible to restore the ON voltage which had fluctuated. For example, a portion of the first semiconductor region 10 (for example, below the second semiconductor region 20) is heated to not less than 350° C. by the heat generation portion 30. As a result of this heating, the stacking faults are reduced, and the ON voltage that had fluctuated is restored.

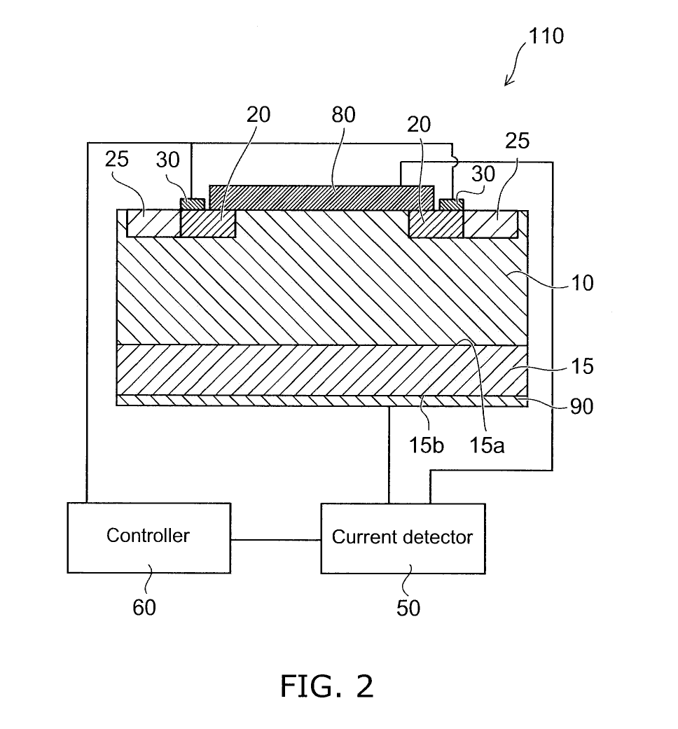

FIG. 2 illustrates a controller.

As illustrated in FIG. 2, the semiconductor device 110 may further include a current detector 50 and a controller 60. At least one of the current detector 50 and the controller 60 may be housed inside the package of the semiconductor device 110 or provided outside the package.

The current detector 50 detects a current value flowing between the first electrode 80 and the second electrode 90. The controller 60 controls the heat generation portion 30 to generate heat when the current value detected by the current detector 50 exceeds a predetermined current value (reference value).

The controller 60 does not allow the heat generation portion 30 to generate heat when the current value detected by the current detector 50 is not more than the reference value. When the controller 60 causes the heat generation portion 30 to generate heat, the controller 60 controls the amount of heat to be generated so that a portion of the first semiconductor region 10 is heated to, for example, not less than 350° C. When the heat generation portion 30 is formed from a material that generates heat by the passage of a current, the controller 60 controls the amount of heat to be generated by controlling the quantity of current.

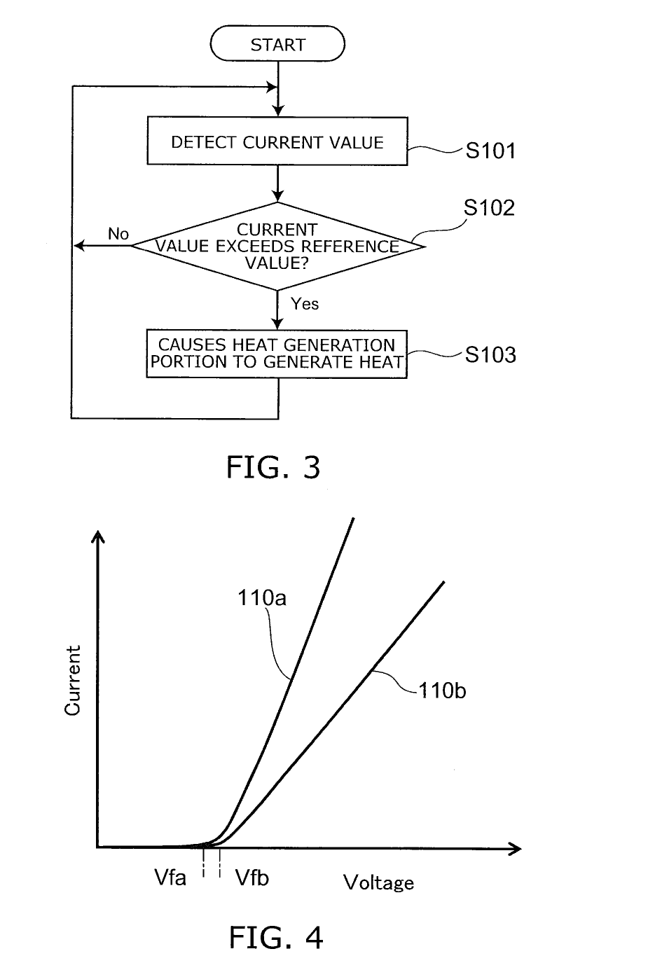

FIG. 3 is a flowchart illustrating a driving method of the semiconductor device according to this embodiment.

As illustrated in FIG. 3, the driving method includes: detecting the current value (step S101); comparing the current value and the reference value (step S102); and generating heat by the heat generation portion (step S103). The driving method is executed by the current detector 50 and the controller 60.

First, as illustrated in step S101, the current value is detected. The current detector 50 detects the current value flowing between the first electrode 80 and the second electrode 90. The detected current value is sent from the current detector 50 to the controller 60.

Next, as illustrated in step S102, the current value is compared with the reference value. The controller 60 compares the current value sent from the current detector 50 with a current value that has been set in advance (reference value). The controller 60, for example, determines whether or not the detected current value exceeds the reference value. The reference value is a value at which stacking faults are considered to be generated in the first semiconductor region 10. The reference value is, for example, a predicted surge current value.

When the controller 60 determines that the detected current value does not exceed the reference value, the routine returns to step S101. When the controller 60 determines that the detected current value exceeds the reference value, the routine proceeds to step S103. If the detected current value has exceeded the reference value (for example, when a surge current has flowed), there is a possibility that stacking faults are generated in the first semiconductor region 10 and that the ON voltage of the semiconductor device 110 will fluctuate.

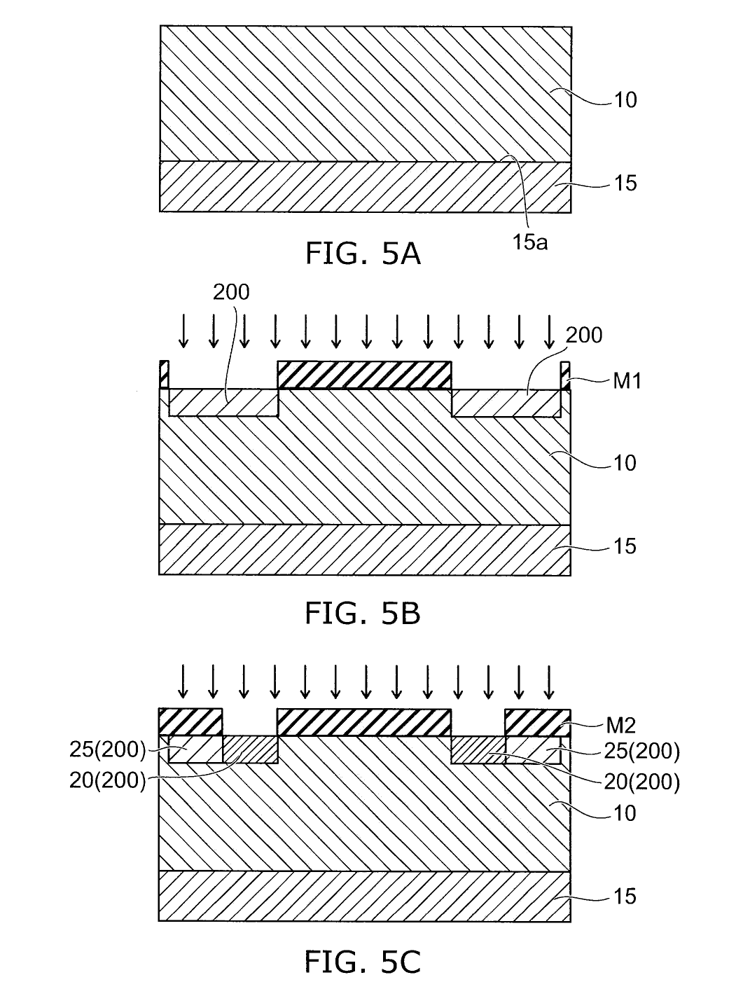

FIG. 4 is a graph showing the current-voltage characteristic.

In FIG. 4, the horizontal axis represents voltage and the vertical axis represents current. The characteristic 110a shown in FIG. 4 is an example of the prescribed characteristic of the semiconductor device 110. In the characteristic 110a, the ON voltage is Vfa. The characteristic 110b is an example of the characteristic of the semiconductor device 110 in a fluctuated state. For example, when stacking faults are generated due to a surge current, the characteristic 110a changes to the characteristic 110b. In the characteristic 110b, the ON voltage is Vfb.

In step S103, the controller 60 causes the heat generation portion 30 to generate heat. For example, when the controller 60 determines that the current value detected by the current detector 50 exceeds the reference value in the decision in step S102 (for example, when there has been a surge current), the controller 60 starts to energize the heat generation portion 30.

As a result of step S103, the heat generation portion 30 generates heat. The heat of the heat generation portion 30 is transmitted to the first semiconductor region 10. A portion of the first semiconductor region 10 is heated to, for example, not less than 350° C. As a result of this heating, the stacking faults generated in the first semiconductor region 10 are reduced. In this way, it is possible to restore the ON voltage which had fluctuated. The heat generation by the heat generation portion 30 may be carried out for a fixed period of time that is set in advance. This fixed period of time is a period of time in which a reduction in stacking faults can be achieved.

The current detector 50 and the controller 60 repeat the process of step S101 to step S103 while the electrical power to the semiconductor device 110 is turned on. In this way, it is possible to restore to the prescribed ON voltage even when the ON voltage of the semiconductor device 110 fluctuates due to stacking faults. For example, the characteristic 110b shown in FIG. 4 is restored to the prescribed characteristic 110a. In this way, the ON voltage Vfb is restored to the prescribed ON voltage Vfa.

### Second Embodiment

Next, a manufacturing method for the semiconductor device according to the second embodiment is described.

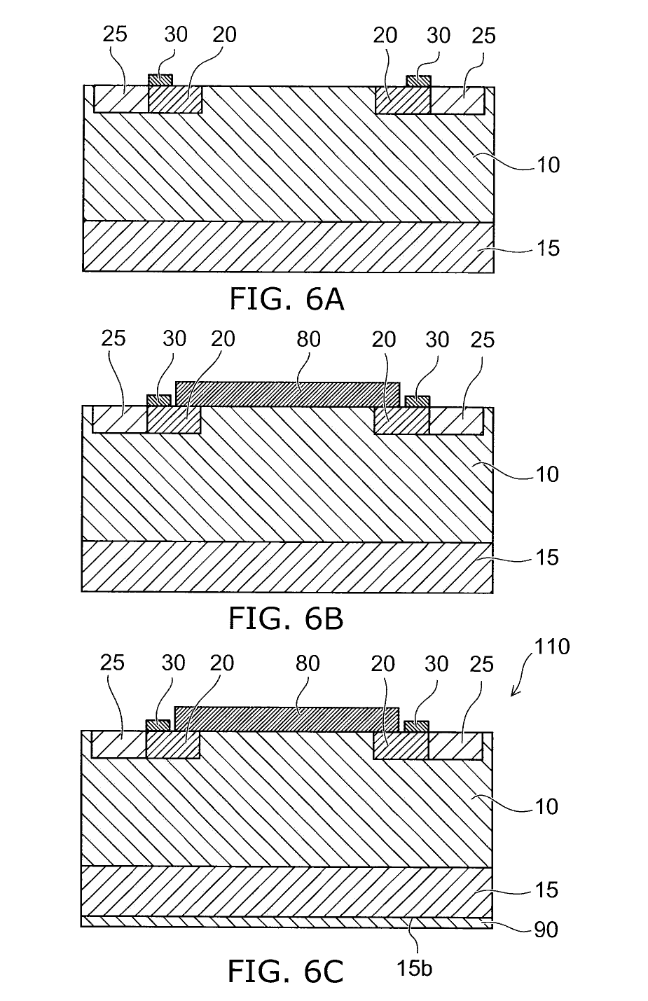

FIGS. 5A to 6C are schematic cross-sectional views illustrating a manufacturing method for the semiconductor device.

A process sequence in the manufacturing method for the semiconductor device 110 is illustrated in FIGS. 5A to 6C.

First, as illustrated in FIG. 5A, an SiC bulk substrate 15 fabricated by a sublimation method is prepared. The doping concentration of the substrate 15 is approximately not less than 1×10¹⁸ cm⁻³ and not more than 1×10²⁰ cm⁻³. In this embodiment, an example in which the doping concentration of the substrate 15 is 5×10¹⁸ cm⁻³ is taken. The conductivity type of the substrate 15 is n⁺ type.

Next, the n⁻ type first semiconductor region 10 is formed on the first surface 15a of the substrate 15. The first semiconductor region 10 is formed on the first surface 15a by, for example, the epitaxial growth method. The doping concentration and the thickness of the n⁻ type first semiconductor region 10 are designed in accordance with the device breakdown voltage and other characteristics. For example, the doping concentration is not less than approximately 8×10¹⁴ cm⁻³ and not more than 1×10¹⁷ cm⁻³, and the thickness is not less than approximately 5 μm and not more than approximately 200 μm.

A buffer layer (not illustrated) having an n-type conductivity type may be formed between the substrate 15 and the first semiconductor region 10 depending on the doping concentration and the thickness of the first semiconductor region 10. The doping concentration of the buffer layer may be, for example, not less than approximately 5×10¹⁷ cm⁻³ and not more than 5×10¹⁸ cm⁻³, and the thickness of the buffer layer may be from approximately several μm to several tens of μm. The buffer layer may be formed by the epitaxial growth method on the first surface 15a of the substrate 15.

Next, as illustrated in FIG. 5B, a mask M1 is formed on the first semiconductor region 10. The mask M1 is an organic material such as a resist or the like or an insulating material, in which openings are provided. Next, ion implantation is carried out via the openings of the mask M1. Here, Al or B ions are implanted. In this way, an ion implantation region 200 is formed with an impurity concentration of not less than, for example, 5×10¹⁶ cm⁻³ and not more than 1×10¹⁹ cm⁻³, and a thickness of not less than 0.1 μm and not more than 2.0 μm. After the ion implantation region 200 is formed, the mask M1 is removed.

Next, as illustrated in FIG. 5C, a mask M2 is formed on the first semiconductor region 10. The mask M2 is an organic material such as a resist, or an insulating material, in which openings are provided. The openings of the mask M2 are smaller than the ion implantation region 200. Next, ion implantation is carried out via the openings of the mask M2. Here, Al or B ions are implanted. In this way, the second semiconductor region 20 is formed in a portion of the ion implantation region 200 with an impurity concentration of, for example, not less than 5×10¹⁷ cm⁻³ and not more than 5×10²⁰ cm⁻³.

A portion of the ion implantation region 200 in which ion implantation is not carried out using the mask M2 becomes the third semiconductor region 25. After the second semiconductor region 20 and the third semiconductor region 25 have been formed, the mask M2 is removed. The second semiconductor region 20 and the third semiconductor region 25 may also be formed by ion implantation with their own individual masks.

Next, the heat generation portion 30 is formed as illustrated in FIG. 6A. The heat generation portion 30 is formed on a portion of the second semiconductor region 20. To form the heat generation portion 30, first, an insulating film such as SiO₂ is formed on the semiconductor device, and the SiC is exposed by opening a portion where the heat generation portion 30 is to be formed. Then, the material (heat generation material) that will form the heat generation portion 30 is formed by, for example, reactive sputtering. Then, a mask is formed on a portion that is to become the heat generation portion 30, and unnecessary heat generation material is removed by reactive ion etching. In this way, the heat generation portion 30 is formed. After the heat generation portion 30 has been formed, the mask is removed. The heat generation portion 30 may be formed by lift-off method.

Next, as illustrated in FIG. 6B, the first electrode 80 is formed. The first electrode 80 is formed apart from the heat generation portion 30 and in contact with the second semiconductor region 20. Ni, for example, is used in the first electrode 80. After the first electrode 80 has been formed, annealing is carried out. In this way, ohmic contact between the first electrode 80 and second semiconductor region 20 is obtained.

Next, as illustrated in FIG. 6C, the second electrode 90 is formed. The second electrode 90 is formed to be in contact with the second surface 15b of the substrate 15. Ni, for example, is used in the second electrode 90. After the second electrode 90 has been formed, annealing is carried out. In this way, ohmic contact between the second electrode 90 and the substrate 15 is obtained. The semiconductor device 110 is completed according to the process given above.

### Third Embodiment

Next, a semiconductor device according to the third embodiment is described.

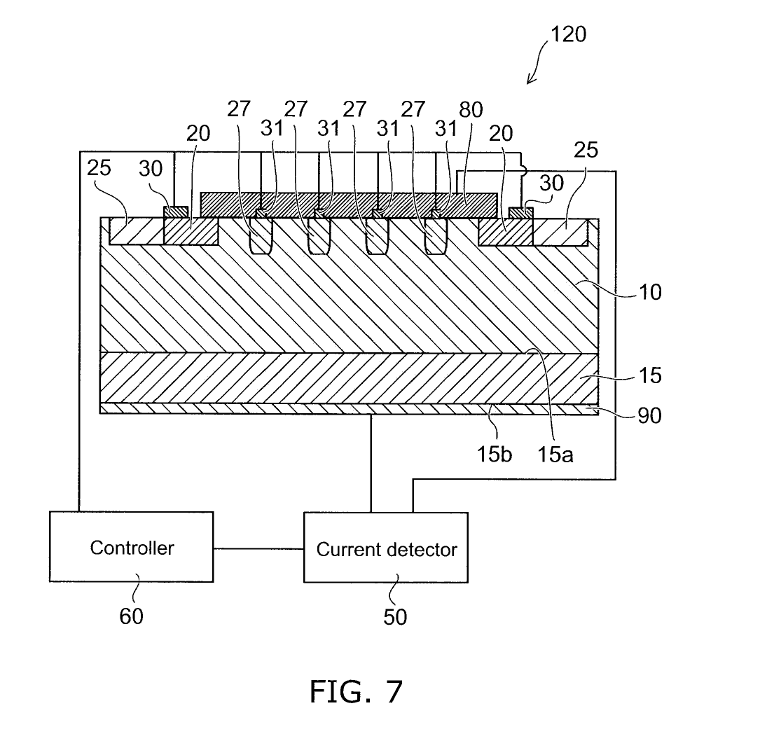

FIG. 7 is schematic cross-sectional view illustrating an example of a semiconductor device according to the third embodiment.

As illustrated in FIG. 7, the semiconductor device 120 according to the third embodiment further includes a fourth semiconductor region 27, in addition to the configuration of the semiconductor device 110 according to the first embodiment.

The fourth semiconductor region 27 is provided on a portion of the first semiconductor region 10 between the first electrode 80 and the first semiconductor region 10. The fourth semiconductor region 27 includes p-type (p⁺ type) SiC. The semiconductor device 120 is, for example, a merged PiN Schottky diode (MPS).

A plurality of the fourth semiconductor regions 27 may be provided at predetermined intervals on a surface side of the first semiconductor region 10. Also, the fourth semiconductor region 27 may be provided in a ring form. When each of the fourth semiconductor region 27 is provided in a ring form, the plurality of fourth semiconductor regions 27 is disposed so that one of the fourth semiconductor regions 27 surrounds an outer side of another of the fourth semiconductor regions 27.

The fourth semiconductor region 27 includes p-type impurities (for example, Al or B). The impurity concentration of the fourth semiconductor region 27 is, for example, not less than 5×10¹⁷ cm⁻³ and not more than 1×10²¹ cm⁻³. The thickness of the fourth semiconductor region 27 is, for example, approximately not less than 0.1 μm and not more than 2.0 μm. The fourth semiconductor region 27 is in ohmic contact with the first electrode 80.

In this semiconductor device 120, when a voltage is applied in the forward direction, a current flows between the first electrode 80 and the first semiconductor region 10 with a low ON voltage, the same as for the SBD. On the other hand, when a voltage is applied in the reverse direction, a depletion layer spreads between the fourth semiconductor region 27 and the first semiconductor region 10, and a high breakdown voltage is obtained, the same as for a PiN.

However, when a large current such as a surge current flows through the semiconductor device 120, holes are injected from the second semiconductor region 20 and the fourth semiconductor region 27 toward the first semiconductor region 10. As a result of this injection of holes, there is a possibility that stacking faults will be generated in the first semiconductor region 10. A fluctuation in the ON voltage of the semiconductor device 120 is generated by the occurrence of the stacking faults.

In the semiconductor device 120 also, the current value flowing between the first electrode 80 and the second electrode 90 is detected by the current detector 50, the same as for the semiconductor device 110. Then, the controller 60 controls the heat generation portion 30 to generate heat when the current value detected by the current detector 50 exceeds a predetermined current value (reference value). When the controller 60 causes the heat generation portion 30 to generate heat, the controller 60 controls the amount of heat to be generated so that a portion of the first semiconductor region 10 is heated to, for example, not less than 350° C. As a result of this heating, the stacking faults are reduced, and the ON voltage that had fluctuated is restored.

In the semiconductor device 120, a heat generation portion 31 may be formed on a portion of the fourth semiconductor region 27. The same material as the heat generation portion 30 may be used as the heat generation portion 31. The heat generation portion 31 is electrically insulated from the first electrode 80.

The controller 60 controls the amount of heat generated by the heat generation portion 31. The controller 60 controls the heat generation portion 31 to generate heat when the current value detected by the current detector 50 exceeds a predetermined current value (reference value). For example, when the heat generation portion 31 is formed from a material that generates heat by the passage of a current, the controller 60 controls the amount of heat to be generated by controlling the quantity of current in the heat generation portion 31. In this way, a portion of the first semiconductor region 10 below the fourth semiconductor region 27 is heated to, for example, not less than 350° C. As a result of this heating, the stacking faults generated in the first semiconductor region 10 are reduced. In this way, the ON voltage of the semiconductor device 120 that had fluctuated due to the stacking faults is restored to the specified ON voltage.

### Fourth Embodiment

Next, a semiconductor device according to the fourth embodiment is described.

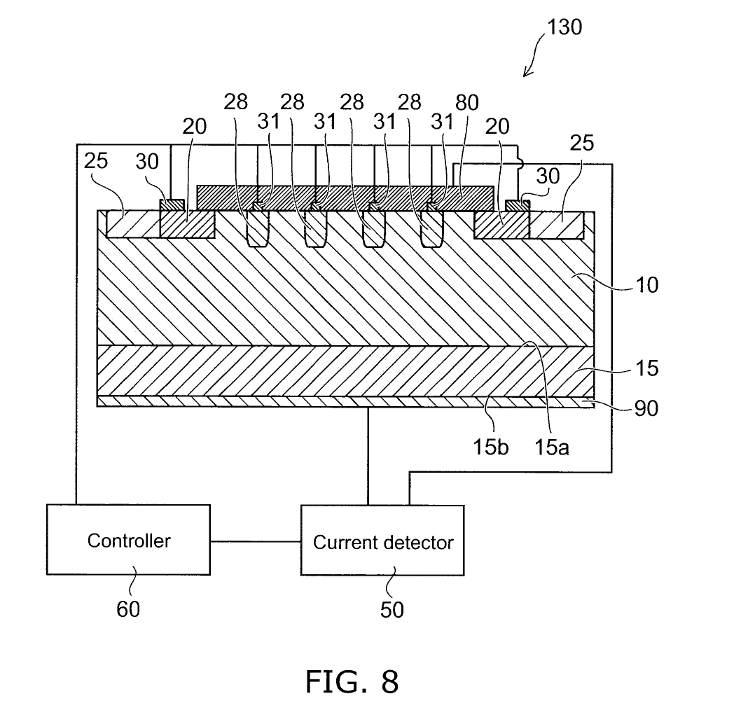

FIG. 8 is schematic cross-sectional view illustrating an example of a semiconductor device according to the fourth embodiment.

As illustrated in FIG. 8, a semiconductor device 130 according to the fourth embodiment includes a fifth semiconductor region 28 instead of the fourth semiconductor region 27 of the semiconductor device 120 according to the third embodiment.

The fifth semiconductor region 28 is provided on a portion of the first semiconductor region 10 between the first electrode 80 and the first semiconductor region 10. The fifth semiconductor region 28 includes p-type (p⁺ type) SiC. The semiconductor device 130 is, for example, a junction barrier Schottky (JBS) diode. The fifth semiconductor region 28 is not in ohmic contact with the first electrode 80.

In this semiconductor device 130, when a voltage is applied in the forward direction, a current flows between the first electrode 80 and the first semiconductor region 10 with a low ON voltage, the same as for the SBD. On the other hand, when a voltage is applied in the reverse direction, a depletion layer spreads between the fifth semiconductor region 28 and the first semiconductor region 10, and a high breakdown voltage is obtained.

In the semiconductor device 130 also, the current value flowing between the first electrode 80 and the second electrode 90 is detected by the current detector 50, the same as for the semiconductor devices 110 and 120. Then, the controller 60 controls the heat generation portion 30 to generate heat when the current value detected by the current detector 50 exceeds a predetermined current value (reference value). When the controller 60 causes the heat generation portion 30 to generate heat, the controller 60 controls the amount of heat to be generated so that a portion of the first semiconductor region 10 is heated to, for example, not less than 350° C. As a result of this heating, the stacking faults are reduced, and the ON voltage that had fluctuated is restored.

In the semiconductor device 130, the heat generation portion 31 may be formed on a portion of the fifth semiconductor region 28, the same as the for semiconductor device 120. The controller 60 controls the amount of heat generated by the quantity of current to the heat generation portion 31, so the stacking faults generated in the first semiconductor region 10 below the fifth semiconductor region 28 are reduced. In this way, the ON voltage of the semiconductor device 130 that had fluctuated due to the stacking faults is restored to the specified ON voltage.

### Fifth Embodiment

Next, the semiconductor device according to a fifth embodiment is described.

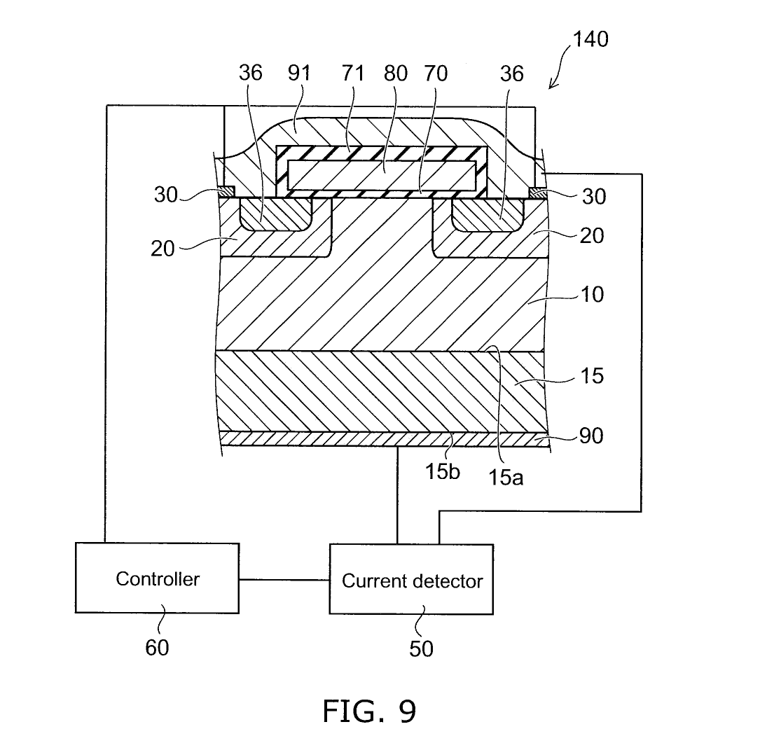

FIG. 9 is a schematic cross-sectional view illustrating the configuration of a semiconductor device according to the fifth embodiment.

As illustrated in FIG. 9, a semiconductor device 140 according to the fifth embodiment includes the substrate 15, the first semiconductor region 10, the second semiconductor region 20, a sixth semiconductor region 36, a gate insulating film 70, the first electrode 80, the second electrode 90, a third electrode 91, and the heat generation portion 30. The semiconductor device 140 is, for example, a metal-oxide-semiconductor field-effect transistor (MOSFET).

The sixth semiconductor region 36 is provided on a portion of the second semiconductor region 20. The sixth semiconductor region 36 includes n⁺ type SiC. The sixth semiconductor region 36 is a MOSFET source region.

The first electrode 80 is a MOSFET gate electrode. The second electrode 90 is a MOSFET domain electrode. The third electrode 91 is a MOSFET source electrode. The first electrode 80, which is the gate electrode, is provided on the second semiconductor region 20 with the gate insulating film 70 disposed therebetween. An insulating film 71 is provided between the first electrode 80 and the third electrode 91. An inversion layer (channel) is formed on the second semiconductor region 20 below the gate insulating film 70.

Next, the operation of the semiconductor device 140 is described.

With a voltage applied to the second electrode 90 that is positive relative to the third electrode 91, when a voltage that exceeds a threshold value is applied to the first electrode 80, a channel is formed near the interface with the gate insulating film 70 in the second semiconductor region 20. In this way, the semiconductor device 140 is in the ON state, and current flows from the second electrode 90 to the third electrode 91.

On the other hand, when the voltage that is lower than the threshold value is applied to the first electrode 80, the channel disappears. In this way, the semiconductor device 140 is in the OFF state, and the flow of current from the second electrode 90 to the third electrode 91 is stopped.

In the semiconductor device 140, the current value flowing between the second electrode 90 and the third electrode 91 is detected by the current detector 50. Then, the controller 60 controls the heat generation portion 30 to generate heat when the current value detected by the current detector 50 exceeds a predetermined current value (reference value). When the controller 60 causes the heat generation portion 30 to generate heat, the controller 60 controls the amount of heat to be generated so that a portion of the first semiconductor region 10 is heated to, for example, not less than 350° C. As a result of this heating, the stacking faults are reduced, and the threshold voltage that had fluctuated is restored.

As described above, according to the semiconductor device and the driving method therefor of the embodiments, it is possible to obtain a stable ON voltage.

Note also that although embodiments and variations have been described above, the present invention is not limited to these. For example, configurations of the above described embodiments or variations which have been added to, removed from, or changed in design in a way that could be easily arrived at by a person skilled in the art, and any appropriate combination of the characteristics of the embodiments is to be construed as being within the scope of the invention.

For example, in the embodiments as described above, an SBD, MPS diode, JBS diode, and MOSFET were described as examples, but the present invention can be applied to other devices that include a p-n junction which are semiconductor devices based on unipolar operation (for example, a junction field effect transistor (J-FET)).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region including n-type silicon carbide;
a second semiconductor region provided on a portion of the first semiconductor region and including p-type silicon carbide;
a first electrode provided on the first semiconductor region and the second semiconductor region; and
a heat generation portion provided on the second semiconductor region.

2. The device according to claim 1, wherein the first semiconductor region forms a Schottky junction with the first electrode, and
the second semiconductor region is in ohmic contact with the first electrode.

3. The device according to claim 1, wherein the heat generation portion is provided apart from the first electrode.

4. The device according to claim 1, wherein the heat generation portion includes a metal oxide.

5. The device according to claim 1, wherein the heat generation portion includes a resistance heating element.

6. The device according to claim 1, wherein the heat generation portion heats the portion of the first semiconductor region to not less than 350° C.

7. The device according to claim 1, further comprising:
a second electrode provided below the first semiconductor region;
a current detector detecting a current value flowing between the first electrode and the second electrode; and
a controller controlling the heat generation of the heat generation portion when the current value detected by the current detector is greater than a predetermined current value.

8. The device according to claim 7, wherein the controller controls the amount of heat generated by the heat generation portion so that the portion of the first semiconductor region is heated to not less than 350° C.

9. The device according to claim 1, wherein the first semiconductor region and the first electrode constitute a Schottky barrier diode.

10. The device according to claim 1, further comprising a third semiconductor region provided on a portion of the first semiconductor region, the third semiconductor region including p-type silicon carbide, and the third semiconductor region having an impurity concentration lower than the impurity concentration of the second semiconductor region.

11. The device according to claim 1, further comprising a fourth semiconductor region provided between the first electrode and the first semiconductor region on a portion of the first semiconductor region, and the fourth semiconductor region including p-type silicon carbide.

12. The device according to claim 1, further comprising an SiC substrate for epitaxial growth of the first semiconductor region.

13. The device according to claim 12, wherein the SiC substrate includes 4H—SiC.

14. The device according to claim 12, wherein the conductivity type of the SiC substrate is n-type.

15. The device according to claim 12, wherein an impurity concentration of the SiC substrate is higher than an impurity concentration of the first semiconductor region.

16. The device according to claim 12, wherein the second electrode is in contact with the SiC substrate.

17. A driving method for a semiconductor device, the semiconductor device including a first semiconductor region including n-type silicon carbide, a second semiconductor region provided on a portion of the first semiconductor region, and including p-type silicon carbide, a first electrode provided on the first semiconductor region and the second semiconductor region, a heat generation portion provided on the second semiconductor region, and a second electrode provided below the first semiconductor region, the method comprising:
detecting a current value flowing between the first electrode and the second electrode of the semiconductor device; and
causing the heat generation portion to generate heat when the current value detected is greater than a predetermined current value.

18. The method according to claim 17, wherein the causing the heat generation portion to generate heat includes heating the portion of the first semiconductor region to not less than 350° C.

19. The method according to claim 17, wherein the first semiconductor region forms a Schottky junction with the first electrode, and
the second semiconductor region is in ohmic contact with the first electrode.

20. The method according to claim 17, wherein the heat generation portion includes a metal oxide.
